(19) United States
(12) Patent Application Publication
(10) Pub. No.: US 2025/0089329 A1
(43) Pub. Date: Mar. 13, 2025

(54) TAPERED INNER SPACER

(71) Applicant: INTERNATIONAL BUSINESS MACHINES CORPORATION, ARMONK, NY (US)

(72) Inventors: Reinaldo Vega, Mahopac, NY (US); Jingyun Zhang, Albany, NY (US)

(21) Appl. No.: 18/466,215

(22) Filed: Sep. 13, 2023

(51) Int. Cl. H01L 29/66; H01L 21/8234; H01L 27/088; H01L 29/06; H01L 29/08; H01L 29/423; H01L 29/775; H01L 29/786

(52) U.S. Cl. CPC H10D 64/017; H10D 30/014; H10D 30/43; H10D 30/6735; H10D 30/6757; H10D 62/121; H10D 62/151; H10D 64/015; H10D 64/021; H10D 84/0128; H10D 84/0147; H10D 84/038; H10D 84/83

(57) ABSTRACT

A transistor includes one or more tapered inner spacers. The tapered inner spacer may include a base region that extends or protrudes beyond a plane that is coplanar with a first sidewall of the gate. The base region(s) may reduce the gate length of the gate adjacent to the base region. When two base regions are associated with the same gate, the two base regions may merge and may be between and/or isolate the gate from the underlying substrate. The tapered inner spacers may result in reduced parasitic capacitances between gate and the substrate and/or between the gate and adjacent source/drain region(s), and/or may reduce current leakage from the gate into the substrate or other underlying structure.

### BACKGROUND

The present disclosure relates to fabrication methods and resulting structures for semiconductor devices. More specifically, the present disclosure relates to fabrication methods and resulting semiconductor integrated circuit (IC) devices that include a gate all around (GAA) transistor that includes a tapered inner spacer.

Conventional transistors, such as semiconductor IC devices, or the like, incorporate planar field effect transistors (FETs) in which current flows through a semiconducting channel between a source and a drain in response to a voltage applied to a control gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET, generally, is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which a majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate.

### SUMMARY

In an embodiment of the present disclosure, a transistor is presented. The transistor includes a substrate, a gate around a plurality of channels and directly upon the substrate, and a tapered inner spacer directly upon the substrate and below a bottommost channel of the plurality of channels. The tapered inner spacer includes a base region that extends beyond a plane that is coplanar with a sidewall of the gate. As the base region of the tapered inner spacer generally reduces the amount of conductive material of the gate adjacent to the base region, the tapered inner spacer may result in reduced parasitic capacitances between gate and the substrate and/or between the gate and adjacent source/drain region(s), and/or may reduce current leakage from the gate to the substrate or other underlying structure.

In an example, the base region reduces a gate length of the gate adjacent to the base region. Similarly, because the base region of the tapered inner spacer generally reduces the amount of conductive material of the gate adjacent to the base region, the tapered inner spacer may result in reduced parasitic capacitances and/or may reduce current leakage.

In an example, the transistor can further include a source/drain (S/D) region directly upon the tapered inner spacer and directly upon respective end surface of the plurality of channels. Similarly, because the base region of the tapered inner spacer relatively increases isolation material between the gate and the S/D region(s), the tapered inner spacer may result in reduced parasitic capacitances between the S/D region(s) and the gate and/or may reduce current leakage.

In an example, the transistor can further include a gate spacer that is located above a topmost channel of the plurality of channels. The gate spacer may further isolate the gate from the S/D region and may result in reduced parasitic capacitances between the S/D region(s) and the gate and/or may reduce current leakage.

In an example, the gate can include a first gate length adjacent to the gate spacer and a second gate length adjacent to the base region that is less than the first gate length. As such, the amount of conductive material of the gate adjacent to the base region is reduced which may result in reduced parasitic capacitances and/or may reduce current leakage.

In an example, the tapered inner spacer can comprise a mirrored inner spacer region and respective sidewalls of the mirrored inner spacer region can be coplanar with respective sidewalls of the gate spacer. As such, the tapered inner spacer may include a region like the existing inner spacers which results in typical conductive material formation of the gate around the channels associated with the inner spacers. Therefore, the conductive material of the gate may be reduced near the bottom of the transistor where such material may be averse and be located near the channels of the transistor where such material is beneficial.

In an example, the base region can include a bottom surface and a tapered surface with a vertical thickness therebetween that decreases in proportion to a degree to which the base region extends inwardly beyond the plane that is coplanar with the sidewall of the gate. As such, the amount of conductive material of the gate adjacent to the base region is reduced which may result in reduced parasitic capacitances and/or may reduce current leakage.

In an embodiment, another transistor is presented. The transistor includes a gate around a plurality of channels, a first tapered inner spacer below a bottommost channel of the plurality of channels, and a second tapered inner spacer below a bottommost channel of the plurality of channels. The first tapered inner spacer includes a first base region that extends inwardly beyond a first plane that is coplanar with a first sidewall (e.g., left-facing sidewall) of the gate and the second tapered inner spacer includes a second base region that extends inwardly beyond a second plane that is coplanar with a second sidewall (e.g., right-facing sidewall) of the gate. As the base regions of the tapered inner spacers generally reduce the amount of conductive material of the gate, adjacent to the base regions, the tapered inner spacers may result in reduced parasitic capacitances and/or may reduce current leakage within the transistor.

In an example, the first base region and the second base region can reduce a gate length of the gate between the first base region and the second base region. Similarly, because the base regions generally reduce the amount of conductive material of the gate adjacent to the base regions, the tapered inner spacers may result in reduced parasitic capacitances and/or may reduce current leakage.

In an example, the transistor can further include a first source/drain (S/D) region directly upon the first tapered inner spacer and directly upon respective first end surfaces of the plurality of channels and a second S/D region directly upon the second tapered inner spacer and directly upon respective second end surfaces of the plurality of channels. Similarly, because the base regions of the tapered inner spacers relatively increases isolation material between the gate and the S/D region(s), the tapered inner spacers may result in reduced parasitic capacitances between the S/D region(s) and the gate and/or may reduce current leakage from the gate into the substrate or other underlying structure.

In an example, the transistor can further include a gate spacer that is located above a topmost channel of the plurality of channels. The gate spacer may further isolate the gate from the S/D region and may result in reduced parasitic capacitances between the S/D region(s) and the gate and/or may reduce current leakage.

In an example, the gate can include a first gate length between the gate spacer and a second gate length between the first base region and the second base region that is less than the first gate length. As such, the amount of conductive material of the gate adjacent to the base region is reduced which may result in reduced parasitic capacitances and/or may reduce current leakage.

In an example, the first tapered inner spacer can include a first mirrored inner spacer region and the second tapered inner spacer can include a second mirrored inner spacer region. Respective sidewalls of the first mirrored inner spacer region can be coplanar with respective sidewalls of the gate spacer and respective sidewalls of the second mirrored inner spacer region can be coplanar with respective sidewalls of the gate spacer. As a result, the tapered inner spacer may include a region like the existing inner spacers which results in typical conductive material formation of the gate around the channels associated with the inner spacers. Therefore, the conductive material of the gate may be reduced near the bottom of the transistor where such material may be averse and be located near the channels of the transistor where such material is beneficial.

In an example, the first base region can comprise a first bottom surface and a first tapered surface with a vertical thickness therebetween that decreases in proportion to a degree to which the first base region extends inwardly beyond the first plane that is coplanar with the first sidewall of the gate. As such, the amount of conductive material of the gate adjacent to the base region is reduced which may result in reduced parasitic capacitances and/or may reduce current leakage.

In an example, the first base region and the second base region can be merged. The merged inner spacer may provide a partial or full dielectric isolation regions between the gate and other transistor regions. This merged inner spacer may render separate isolation structures, like bottom dielectric isolation (BDI) regions, obsolete or disadvantageous.

In an example, the merged first base region and second base region can be between the gate and a substrate. The merged inner spacer may provide a partial or full dielectric isolation region between the substrate and the gate.

In another embodiment, a method of forming a semiconductor integrated circuit (IC) device is presented. The method includes forming a graded nanolayer directly upon a substrate, indenting the graded nanolayer to form a tapered inner spacer opening, and forming a tapered inner spacer within the tapered inner spacer opening. The tapered inner spacers may provide for the reduction of conductive material of a subsequently formed gate, which may result in reduced parasitic capacitances and/or may reduce current leakage.

In an example, the method can further include forming a sacrificial nanolayer directly upon the graded nanolayer. As such, the graded nanolayer may be apart of nanolayer fabrication processes utilized to fabricate a nanolayer transistor.

In an example, the method can further include forming a gate directly upon the tapered inner spacer. The tapered inner spacers may provide for the reduction of conductive material of the gate, which may result in reduced parasitic capacitances and/or may reduce current leakage.

In an example, the tapered inner spacer can include a base region and the base region can reduce a gate length of the gate adjacent to the base region. The base region of the tapered inner spacer may provide for the reduction of conductive material of the gate, which may result in reduced parasitic capacitances and/or may reduce current leakage.

In another embodiment, yet another transistor is presented. The transistor includes a gate around a channel that extends beyond both a first sidewall of the gate (e.g., left-facing sidewall) and a second sidewall of the gate (e.g., right-facing sidewall). The transistor further includes a tapered inner spacer directly upon the gate and directly upon a bottom surface of the channel. The tapered inner spacer includes a base region that protrudes beyond the first sidewall of the gate toward the second sidewall of the gate, thereby reducing associated conductive gate material. As the base region of the tapered inner spacer generally reduces the amount of conductive material of the gate that is adjacent to the base region, the tapered inner spacer may result in reduced parasitic capacitances between gate and other structures, such as a substrate, source/drain region(s), and/or may reduce current leakage from the gate.

In an example, the base region reduces a gate length of the gate adjacent to the base region. As such, the tapered inner spacer may result in reduced parasitic capacitances between gate and other structures, such as a substrate, source/drain region(s), and/or may reduce current leakage from the gate.

In an example, the gate has a first gate length above the channel and a second gate length adjacent to the base region that is less than the first gate length. As such, the tapered inner spacer may result in reduced parasitic capacitances between gate and other structures, such as a substrate, source/drain region(s), and/or may reduce current leakage from the gate.

In an example, the tapered inner spacer further comprises a mirrored inner spacer region and the gate has the first gate length adjacent to the mirrored inner spacer region. As such, the gate may have a larger gate length next to the mirrored inner spacer region and a reduced gate length adjacent to the base region that can result in reduced parasitic capacitances between gate and other structures, such as a substrate, source/drain region(s), and/or may reduce current leakage from the gate.

In an example, the base region includes a bottom surface and a tapered surface with a vertical thickness therebetween that decreases in proportion to a degree to which the base region protrudes beyond the first sidewall of the gate toward the second sidewall of the gate. As such, the amount of conductive material of the gate adjacent to the base region is reduced which may result in reduced parasitic capacitances and/or may reduce current leakage.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts a cross section view of a semiconductor IC device that includes a tapered inner spacer, according to one or more embodiments of the disclosure.

FIG. 2 depicts a cross section view of a semiconductor IC device that includes a tapered inner spacer, according to one or more embodiments of the disclosure.

FIG. 3 depicts a cross section fabrication view of a semiconductor IC device that is to include a tapered inner spacer, according to one or more embodiments of the disclosure.

FIG. 4 depicts a cross section view of a graded sacrificial nanolayer, according to one or more embodiments of the disclosure.

FIG. 5 through FIG. 15 depict respective cross section fabrication views of a semiconductor IC device that includes or is to include a tapered inner spacer, according to one or more embodiments of the disclosure.

FIG. 16 depicts a flowchart of a method of fabricating a semiconductor IC device that includes a tapered inner spacer, according to one or more embodiments of the disclosure.

FIG. 17 depicts a cross section view of a tapered inner spacer, according to one or more embodiments of the disclosure.

### DETAILED DESCRIPTION

Nanosheet transistors that include a gate that is fabricated directly upon a substrate, which are referred to herein as bulk nanosheet transistors, may be viewed as more accessible for process integration relative to nanosheet transistors with a partial or full dielectric isolation region between the substrate and their respective transistor regions. However, the architecture of bulk nanosheet transistors has traditionally resulted in relatively larger parasitic capacitances between the gate and the substrate and the gate and the source/drain (S/D) region and/or relatively increased gate current leakage. To mitigate such effects, bulk nanosheet transistors have relatively higher doping concentrations within their respective well region(s) and/or punch-through-stop region(s). Further, due to the absence of the partial or full dielectric isolation region(s), there is relatively less control of the S/D recess depth, due to a lack of a robust etch stop. The present embodiments of the disclosure provide for a tapered inner spacer profile that may be utilized by bulk nanosheet transistors that result in reduced parasitic capacitances between the gate and the substrate and the gate and the source/drain (S/D) region and/or relatively reduced gate current leakage. The tapered inner spacer may be fabricated by incorporating a graded sacrificial nanolayer into the nanolayer stack. The graded sacrificial nanolayer may be a Silicon Germanium layer which may have a relatively lower Germanium concentration at its top and a higher Germanium concentration at its bottom. The relatively high Germanium concentration may provide adequate selectivity with respect to the underlying substrate and may provide for relatively increased control of the S/D region recess depth.

The flowcharts and cross-sectional diagrams in the drawings illustrate a method of fabricating semiconductor IC device, such as a processor, filed programmable gate array (FPGA), memory module, or the like. In some alternative implementations, the fabrication steps may occur in a different order that that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail herein. Moreover, the various tasks and process steps described herein can be incorporated into a more comprehensive procedure or process having additional steps or functionality not described in detail herein. Various steps in the manufacture of semiconductor devices are well known and so, in the interest of brevity, many conventional steps will only be mentioned briefly herein or will be omitted entirely without providing the well-known process details.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, by diffusion and/or by ion implantation. These doping processes are followed by furnace annealing or by rapid thermal annealing (RTA). Annealing serves to activate the implanted dopants. Films of both conductors (e.g., polysilicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, for some transistor architectures, integration of the transistors with a backside back end of line (BEOL) network is one of the key challenges to providing increasing packaged IC device densities and performance increases. By incorporating the BEOL network into the semiconductor IC device, there may be a logical and/or functional separation between electrical signal routing and electrical power routing through the semiconductor IC device which may ease routing congestion in some applications. Currently, there is a need to dissipate charge build up that occurs during the fabrication of the backside BEOL network and to limit the ill effects thereof (e.g., gate isolation damage, reduction of device yield, or the like).

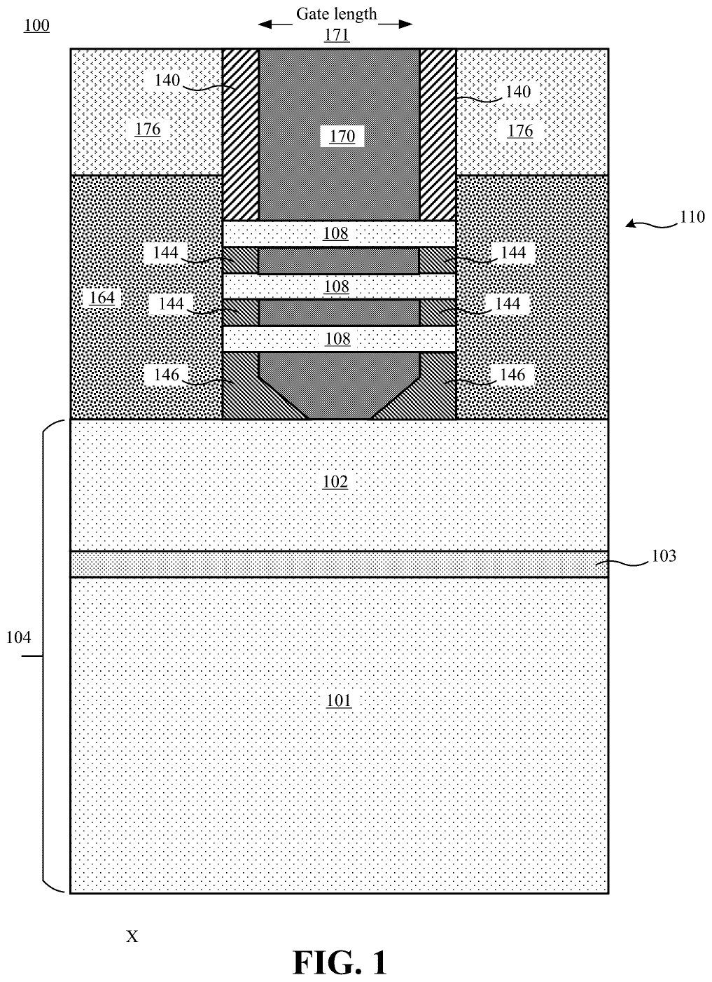

Referring now to the drawings in which like numerals represent the same or similar elements and initially to FIG. 1, this figure depicts a cross-sectional view of a semiconductor IC device 100 that includes a nanosheet transistor 110 with one or more tapered inner spacers 146, according to embodiments. The nanosheet transistor 110 may further include a replacement gate structure 170, nanosheet or nanowire channels, which may be referred to herein as active nanolayers 108, a source region (e.g., a first source/drain (S/D) region 164), and a drain region (e.g., a first source/drain (S/D) region 164).

The tapered inner spacer(s) 146 may provide for partial or full dielectric isolation region between a substrate 104 and other respective transistor 110 regions, such as replacement gate structure 170, source/drain (S/D) region 164, or the like. The tapered inner spacer(s) 146 may reduce or eliminate the need for a separate isolation structure, such as a bottom dielectric isolation (BDI) region or the like, which may reduce semiconductor IC device 100 fabrication complexities.

The tapered inner spacer(s) 146 may be located between the substrate 104 and a bottommost active nanolayer 108, which serve as the channel between the S/D regions 164 of the nanosheet transistor 110. The tapered inner spacer(s) 146 include a base region and a mirrored inner spacer region that are integrally formed with one another. The base region extends inwardly beyond one or more planes formed by one or more associated sidewall(s) of the replacement gate structure 170. A vertical thickness or height of the base region may decrease as it extends inwardly in proportion to a horizontal dimension into the replacement gate structure 170 to which it extends. In other words, the base region may include a wedge having its narrowest point arranged most inwardly and its widest point arranged most outwardly relative to a midline of the replacement gate structure 170. The mirrored inner spacer region substantially shares the same geometry of other inner spacers 144 within the nanosheet transistor 110. In an illustrative geometry, the base region of the tapered inner spacer(s) 146 is below the mirrored inner spacer region of the tapered inner spacer(s) 146. In some embodiments, there may be a gap between the mirrored inner spacer region and the base region, due to the presence of residual sacrificial thin nanolayer 107 at the time of tapered inner spacer 146 formation.

The tapered inner spacer(s) 146 may result in reduced parasitic capacitances between the replacement gate structure 170 and the substrate 104 and the replacement gate structure 170 and the S/D region(s) 164, and/or may relatively reduce current leakage from replacement gate structure 170 into the substrate 104 or other underlying structure.

As depicted in FIG. 1, the nanosheet transistor 110 may include two tapered inner spacers 146 that do not merge. This may, for example, occur when the gate length 171 of replacement gate structure 170 is sufficiently high (e.g., in long channel length transistors). In this implementation, as the two tapered inner spacers 146 do not merge, the replacement gate structure 170 may be directly upon the substrate 104.

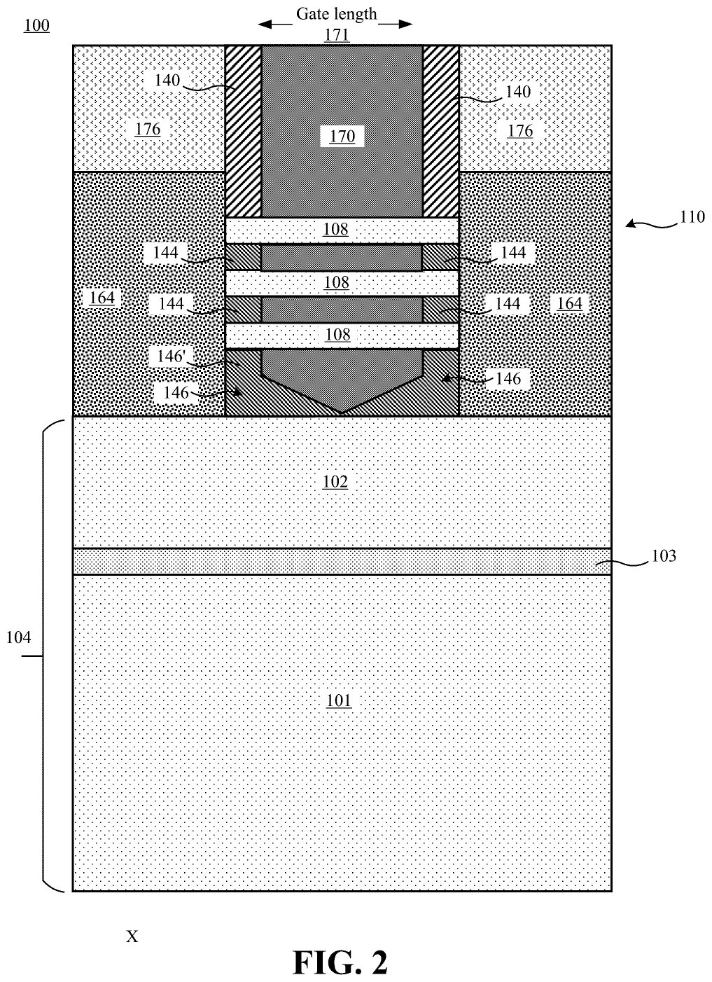

As depicted in FIG. 2, the nanosheet transistor 110 may include a single tapered inner spacer 146′ that may be formed by the merging of two opposite facing tapered inner spacers 146. This may, for example, occur when the gate length 171 of replacement gate structure 170 is sufficiently low (e.g., in short channel length transistors). In this implementation, as the two tapered inner spacers 146 merge and cover the underlying substrate 104, the replacement gate structure 170 may be directly upon the tapered inner spacer 146′. In other words, the tapered inner spacer 146′ may exist between the replacement gate structure 170 and the substrate 104.

In illustrated examples, the semiconductor IC device 100 may include one or more nanosheet transistors 110. The nanosheet transistors 110 provide a relatively small transistor footprint by arranging the channel as vertically stacked active nanolayers 108. The nanosheet transistors 110 include a source region (a first S/D region 164), a drain region (a second S/D region 164), and vertically stacked active nanolayers 108 between the source and drain regions. The replacement gate structure 170 vertically surrounds the vertically stacked active nanolayers 108 and regulates electron flow through the vertically stacked active nanolayers 108 between the S/D regions 164.

For n-type nanolayer transistors 110, the active nanolayers 108 may be silicon (Si). For p-type nanolayer transistors 110, the active nanolayers 108 can be SiGe or Si. Forming active nanolayers 108 from SiGe or Si, depending upon the nanolayer transistors 110 type, may provide for superior channel electrostatics control, which is beneficial for continuously scaling gate lengths.

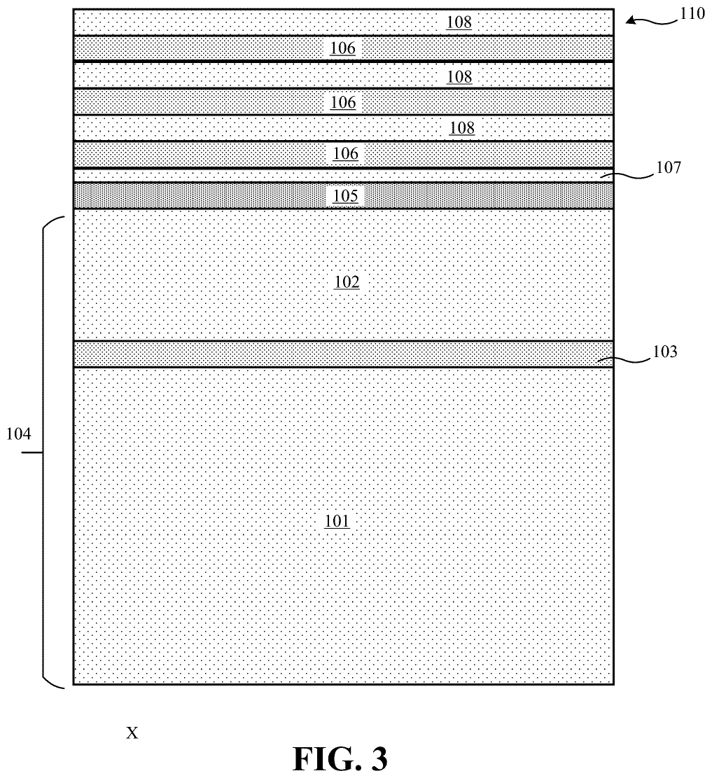

In the illustrated example, semiconductor IC device 100 may further include substrate 104, which, at certain stages of fabrication, may include a lower substrate 101, an etch stop layer 103, and an upper substrate 102. Semiconductor IC device 100 may further include one or more replacement gate structures 170, gate spacers 140, and/or interlayer dielectric (ILD) 176. The replacement gate structure 170 may include a high-K layer, a work function gate, and a conductive fill gate. The vertically stacked active nanolayers 108 may be arranged within a nanolayer stack, the formation of which in association with the fabrication of IC device 100 are described below with reference to FIG. 3 through FIG. 15.

FIG. 3 depicts a cross-sectional view of the semiconductor IC device 100 after initial fabrication operations, in accordance with embodiments of the present disclosure. In these initial fabrication stages, nanolayers are formed upon a substrate 104.

The substrate 104 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon (Si) is the predominantly used semiconductor material in wafer fabrication, alternative semiconductor materials can be employed, such as, but not limited to, gallium arsenide, gallium nitride, cadmium telluride, zinc selenide, and III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements. In another implementation, the substrate 104 includes an upper substrate 102, a lower substrate 101, and an insulator layer between the upper substrate and the lower substrate. The upper and lower substrates may be comprised of any other suitable material(s) than those listed above, and the insulator layer may be a dielectric layer, such as an oxide, and may be referred to as a buried oxide (BOX) substrate. In another implementation, the substrate 104 includes the upper substrate 102, the lower substrate 101, and an etch stop layer 103 between the upper substrate 102 and the lower substrate 101. The etch stop layer 103 may be a dielectric layer and may be any dielectric with etch selectivity to one or both the upper substrate 102 and/or the lower substrate 101.

Nanolayers may be formed upon the substrate 104 by forming a graded sacrificial nanolayer 105 directly on an upper surface of the substrate 104 and a thin sacrificial nanolayer 107 upon the graded sacrificial nanolayer 105. Next, alternating blanket layers of sacrificial nanolayers 106 and active nanolayers 108 may be formed.

In an illustrative example, the graded nanolayer 105 is composed of silicon-germanium (e.g., SiGe, where the Ge ranges from about 20-30% at the top of the graded nanolayer 105 degrading down to from about 50-80% at the bottom of the graded nanolayer 105). Further, in an illustrative example, each of the sacrificial nanolayers 106 are composed of silicon-germanium (e.g., SiGe, where the Ge ranges from about 20-30%). Still further, in an illustrative example, the thin sacrificial nanolayer 107 and each of the active nanolayers 108 are composed of silicon.

In the illustrated semiconductor IC device 100, there are a total of three sacrificial nanolayers 106, three active nanolayers 108, one graded nanolayer 105, and one thin sacrificial nanolayer 107. However, it should be appreciated that any suitable number of nanolayers may be utilized.

Although it is specifically contemplated that the sacrificial nanolayers 106 and the graded nanolayer 105 can be formed from SiGe and that the active nanolayers 108 and thin sacrificial nanolayer 107 can be formed from Si, it should be understood that any appropriate materials can be used instead, as long as the two semiconductor materials have etch selectivity with respect to one another.

The alternating nanolayers can be deposited by any appropriate mechanism. The alternating blanket nanolayers can be epitaxially grown from one another, but alternate deposition processes, such as chemical vapor deposition (CVD), physical vapor deposition (PVD), atomic layer deposition (ALD), or gas cluster ion beam (GCIB) deposition, are also contemplated.

In certain embodiments, the sacrificial nanolayers 106, the graded nanolayer 105, and the active nanolayers 108 have a vertical thickness ranging, for example, from approximately 3 nm to approximately 20 nm. In certain embodiments, the thin sacrificial nanolayer 107 is generally adequately thin relative to active nanolayers 108 so that it may be consumed during subsequent fabrication stages while the active nanolayers 108 adequately remain. Although the range of 3-20 nm is cited as an example range of thickness of the sacrificial nanolayers 106 and active nanolayers 108, other thickness of these nanolayers may be used. In certain examples, certain of the sacrificial nanolayers 106 and active nanolayers 108 may have different thicknesses relative to one another.

In certain implementations, it may be desirable to have a small vertical spacing (VSP) between adjacent active nanolayers 108 in a stack of nanolayers to reduce the parasitic capacitance and to improve circuit speed. For example, the VSP (the distance between adjacent active nanolayers 108) may range from 5 nm to 15 nm. However, the VSP must be of a sufficient value to accommodate the replacement gate structure that will be formed in the spaces created by removal of respective portions of the sacrificial nanolayers 106.

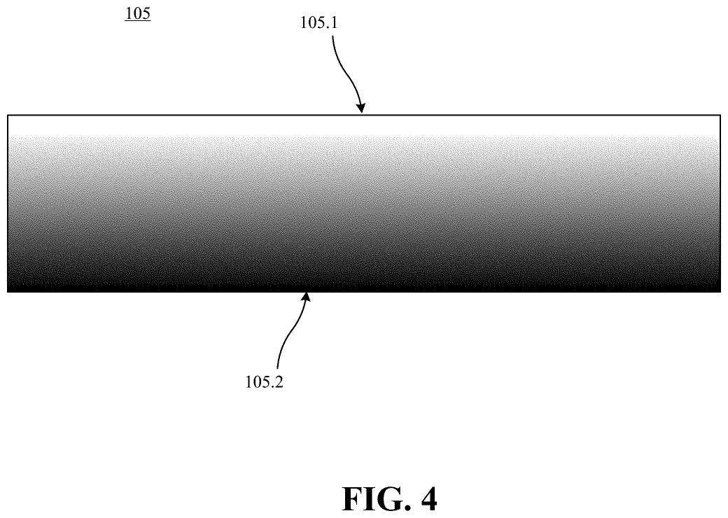

FIG. 4 depicts a cross section view of graded sacrificial nanolayer 105, according to one or more embodiments of the disclosure. Graded sacrificial nanolayer 105 includes a bottom surface 105.2 and a top surface 105.1. Bottom surface 105.2 may be formed from the top surface of substrate 104 and may therefore be directly upon the top surface of substrate 104. For example, graded sacrificial nanolayer 105 may be epitaxially grown from substrate 104.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

Graded sacrificial nanolayer 105 includes a gradually and/or uniformly changing microstructure from a material that has a first composition ratio at a first internal location of graded sacrificial nanolayer 105 (e.g., the top surface 105.1) to a second composition ratio at a second internal location of graded sacrificial nanolayer 105 (e.g., the bottom surface 105.2) with an increased percentage of material that is etched during the removal of sacrificial nanolayers 107. For example, when sacrificial nanolayers 107 and graded sacrificial nanolayer 105 are composed of SiGe, graded sacrificial nanolayer 105 includes the gradually and/or uniformly changing SiGe microstructure that has a first composition ratio at a first internal location of graded sacrificial nanolayer 105 (e.g., where the Ge ranges from about 20-30% at the top surface 105.1) to a second composition ratio at an second internal location of graded sacrificial nanolayer 105 (e.g., where the Ge ranges from about 50-80% the bottom surface 105.2).

In an illustrative implementation, at the top surface 105.1 there may be a 20% Ge concentration and at the bottom surface 105.2 there may be a 60% Ge concentration, with the Ge concentration gradually and/or uniformly changing from 20% at the top surface 105.1 to 60% at the bottom surface. As such, graded sacrificial nanolayer 105 includes a gradient of gradually and/or uniformly changing microstructure from the first material concentration at top surface 105.1 to the second material concentration at the bottom surface 105.2. This gradient is depicted by gradually and/or uniformly darkening from mostly white nearest top surface 105.1 to mostly black nearest bottom surface 105.2. The direction of the gradient may be generally vertical, as depicted, between substantially horizontal top surface 105.1 and bottom surface 105.2 (e.g., the concentration of Ge may be substantially the same across the length of the graded sacrificial nanolayer 105 at the same vertical thickness). This gradient may be uniform if the change in material concentration is constant across the vertical thickness of the graded sacrificial nanolayer 105. The actual change in material concentration is dependent upon, for example, the epitaxial growth parameters of the graded sacrificial nanolayer 105.

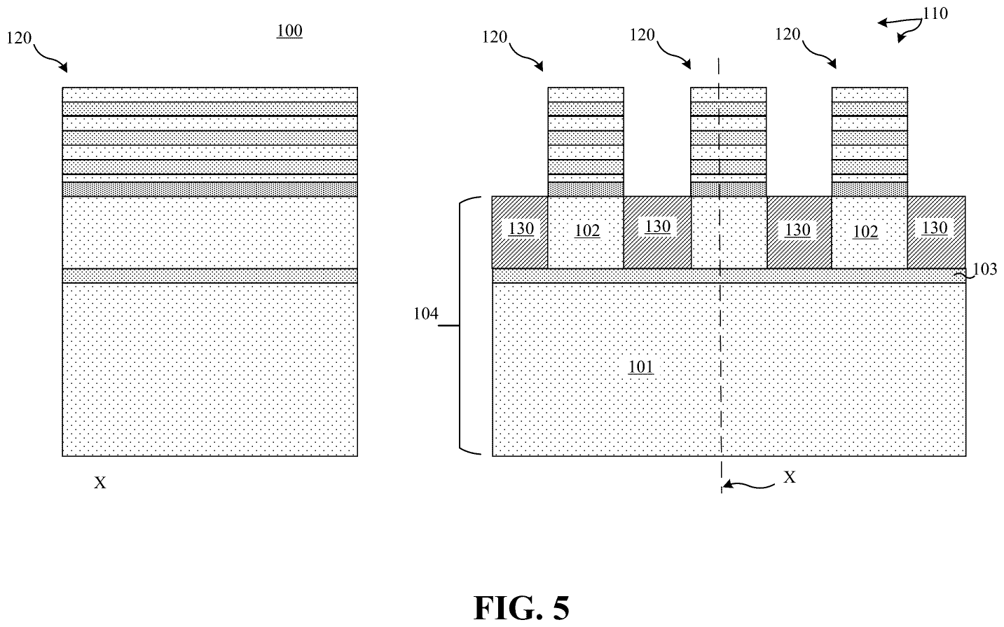

FIG. 5 depicts a cross-sectional view of the semiconductor IC device 100 after fabrication operations, in accordance with embodiments of the present disclosure. In the depicted fabrication stages, the nanolayers are patterned into nanolayer stacks 120 and one or more shallow trench isolation regions 130 are formed. For clarity, orthogonal cross-sectional views are depicted in FIG. 3 a plane (X plane) upon which the cross-sectional views of the remaining structural drawings is established.

To form one or more nanolayer stacks 120, a mask layer (not shown) is formed on the uppermost nanolayer. The mask layer may be comprised of any suitable mask or lithography material(s). The mask layer may be patterned and used to perform the nanolayer stack 120 patterning process. In the nanolayer stack 120 patterning process, any suitable material removal process (e.g., reactive ion etching or RIE) may be used to remove portions of the alternating nanolayers down to the upper substrate 102, down to the etch stop layer 103, or the like. Following the nanolayer stack 120 patterning process, one or more nanolayer stacks 120 are formed. As depicted, within each nanolayer stack 120 there is a graded sacrificial nanolayer 105, thin sacrificial nanolayer 107, and alternating sacrificial nanolayers 106 and active nanolayers 108 (all indicated in FIG. 3) formed from the associated nanolayers, respectively. Subsequently, the mask layer may be removed.

The removal of undesired portion(s) of the nanolayers may further remove undesired portions upper substrate 102 that are adjacent to respective footprints of nanolayer stacks 120 to form STI region openings. The etch may be timed or otherwise controlled to stop the removal of the upper substrate 102 such that the depth or bottom of the one or more STI region openings has a predetermined or desired dimension. Alternatively, the etch may utilize the etch stop layer 103 to effectively stop the etch to form the depth or bottom of the one or more STI region openings.

A STI region 130 may be formed within the substrate 104 below and adjacent to the nanolayer stacks 120 within the STI region openings. For example, one or more STI regions 130 may be formed by depositing isolation material within the STI region openings adjacent to the one or more nanolayer stacks 120. A top surface of the one or more STI regions 130 may be coplanar with a top surface of substrate 104. The STI region(s) 130 may be formed by depositing STI isolation material, such as a dielectric, upon the substrate 104 to a thickness such that the top surface of the STI isolation material is coplanar with the top surface of the substrate 104. The one or more STI regions may have a volume that sufficiently electrically isolates components or features of neighboring transistors, or the like, and/or may sufficiently electrically isolate neighboring nanolayer stacks 120.

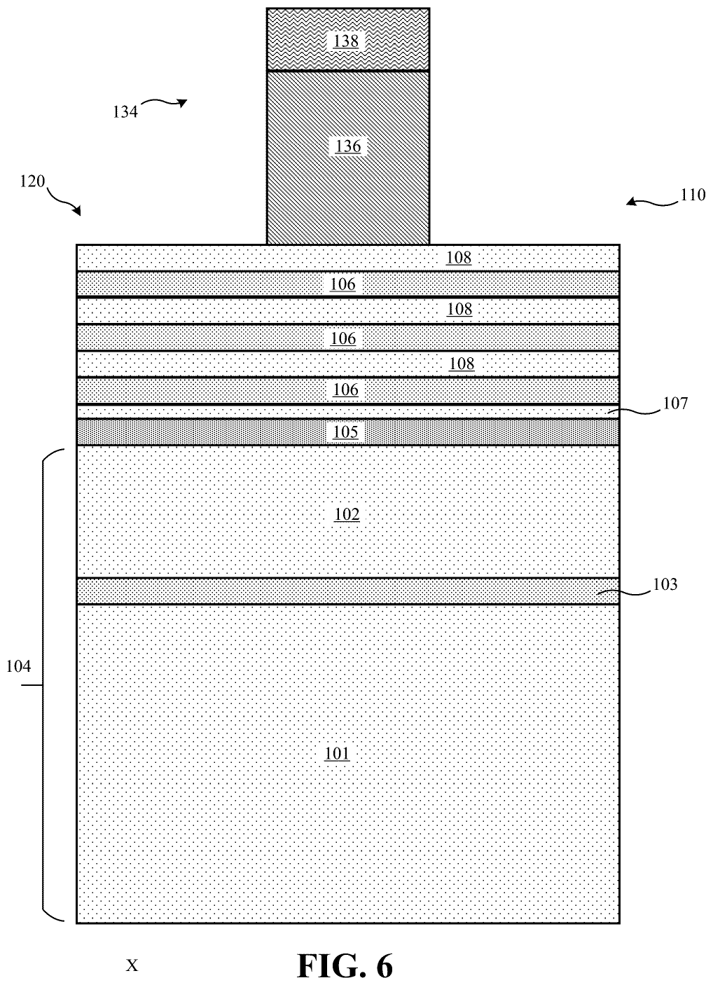

FIG. 6 depicts a cross-sectional view of the semiconductor IC device 100 after fabrication operations, in accordance with embodiments of the present disclosure. In the depicted fabrication stages, one or more sacrificial gate structures 134 are formed upon the upon STI regions 130 (not shown in the depicted cross-section) and upon and around the one or more nanolayer stacks 120. The one or more sacrificial gate structures 134 may include a sacrificial gate liner (not shown), a sacrificial gate 136, and a sacrificial gate cap 138.

The sacrificial gate structures 134 may be formed by initially depositing the sacrificial gate liner layer (e.g., a dielectric, oxide, or the like) upon the one or more STI regions 130 and upon and around the one or more nanolayer stacks 120. The sacrificial gate structures 134 may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the one or more nanolayer stacks 120. The sacrificial gate structures 134 may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures 134 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner (not shown), the sacrificial gate 136, and the sacrificial gate cap 138, respectively, of each of the one or more sacrificial gate structures 134.

One or more sacrificial gate structures 134 can be formed on targeted regions or areas of semiconductor IC device 100 to define the length of one or more nanosheet transistors 110 and to provide sacrificial material for yielding targeted nanosheet transistor 110 structure(s) in subsequent processing. According to an example, each sacrificial gate structure 134 can have a height of between approximately 50 nm and approximately 200 nm, and a length of between approximately 10 nm and approximately 200 nm.

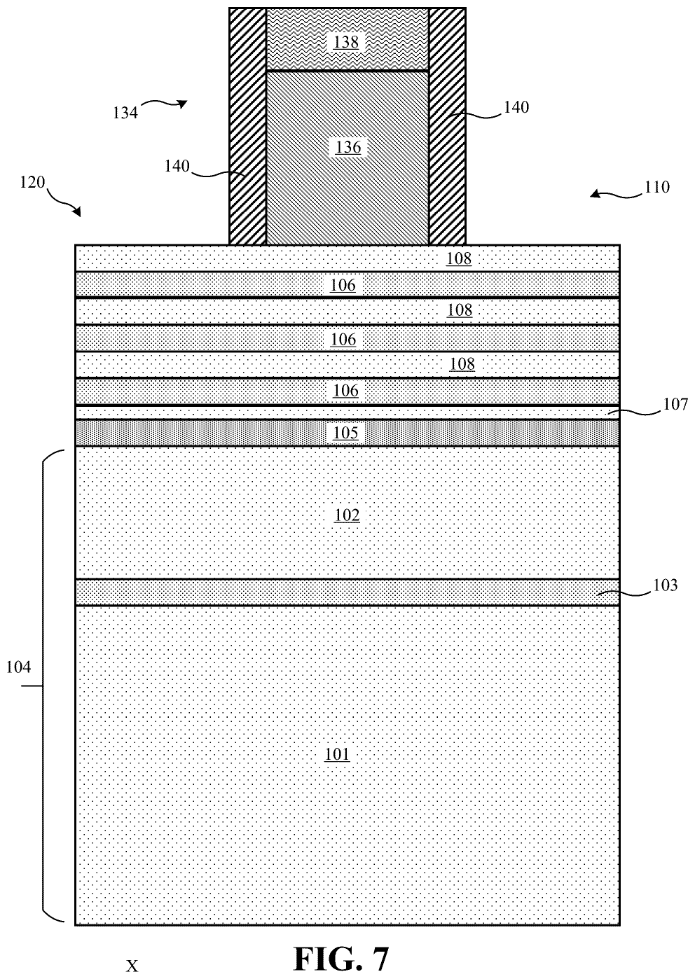

FIG. 7 depicts a cross-sectional view of the semiconductor IC device 100 after fabrication operations, in accordance with embodiments of the present disclosure. In the depicted fabrication stages, gate spacer(s) 140 are formed on the one or more sacrificial gate structures 134.

The gate spacer(s) 140 may be respectively formed upon the one or more STI regions 130, upon and around the one or more nanolayer stacks 120, and upon and around each of the one or more sacrificial gate structures 134. In one example, gate spacers 140 may be formed of a dielectric material(s), such as such as silicon nitride, SiBCN, SiNC, SIN, SiCO, SiNOC, a combination thereof, or the like.

The one or more gate spacers 140 may be formed by a deposition of a blanket gate spacer dielectric material. Excess, undesired, and/or exposed blanket gate spacer dielectric material may be subsequently removed by a substrative removal technique, such as an etch. For example, a directional etch may remove exposed horizontal portion(s) of the blanket gate spacer dielectric material while also leaving vertical portion(s) of the blanket gate spacer dielectric material, upon the sidewall perimeter of each of the one or more sacrificial gate structures 134, intact.

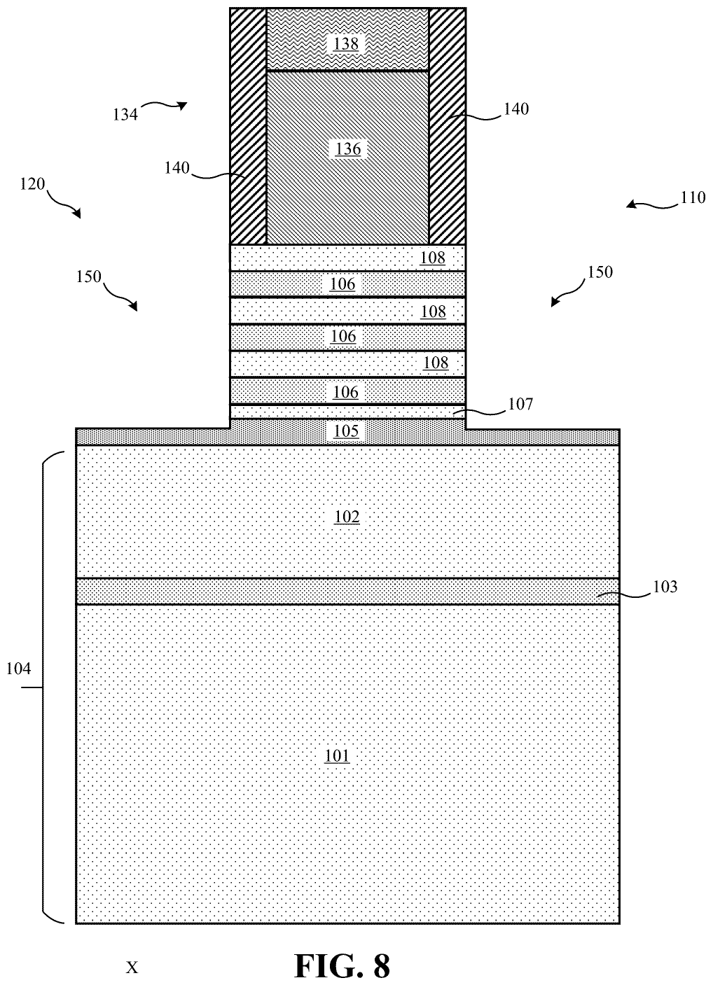

FIG. 8 depicts a cross-sectional view of the semiconductor IC device 100 after fabrication operations, in accordance with embodiments of the present disclosure. In the depicted fabrication stages, source/drain (S/D) recesses 150 are formed within the one or more nanolayer stacks 120 between gate spacers 140 that are associated with neighboring sacrificial gate structures 134. In other words, a single nanolayer stack 120 may be separated into multiple nanolayer stacks 120, each located underneath a sacrificial gate structure 134, by the formation of one or more S/D recesses 150.

The one or more S/D recesses 150 may be formed between adjacent sacrificial gate structures 134 by removing respective portions of the sacrificial nanolayers 106 and active nanolayers 108 that are between gate spacers 140 of adjacent or neighboring sacrificial gate structures 134. The one or more S/D recesses 150 may be formed to a depth to stop at or within the graded sacrificial nanolayer 105. In an illustrative example, the one or more S/D recesses 150 may be formed to a depth to stop between the top surface 105.1 and the bottom surface 105.2 (shown in FIG. 4) of the graded sacrificial nanolayer 105.

In this manner, the active nanolayers 108 and sacrificial nanolayers 106 of respective nanolayer stack 120 are separated. In the separation, respective portions of the sacrificial nanolayers 106 and the active nanolayers 108 that are located below the gate spacers 140 and below the sacrificial gate structures 134 may be retained. The undesired portions of the nanolayers may be removed by etching or other subtractive removal techniques.

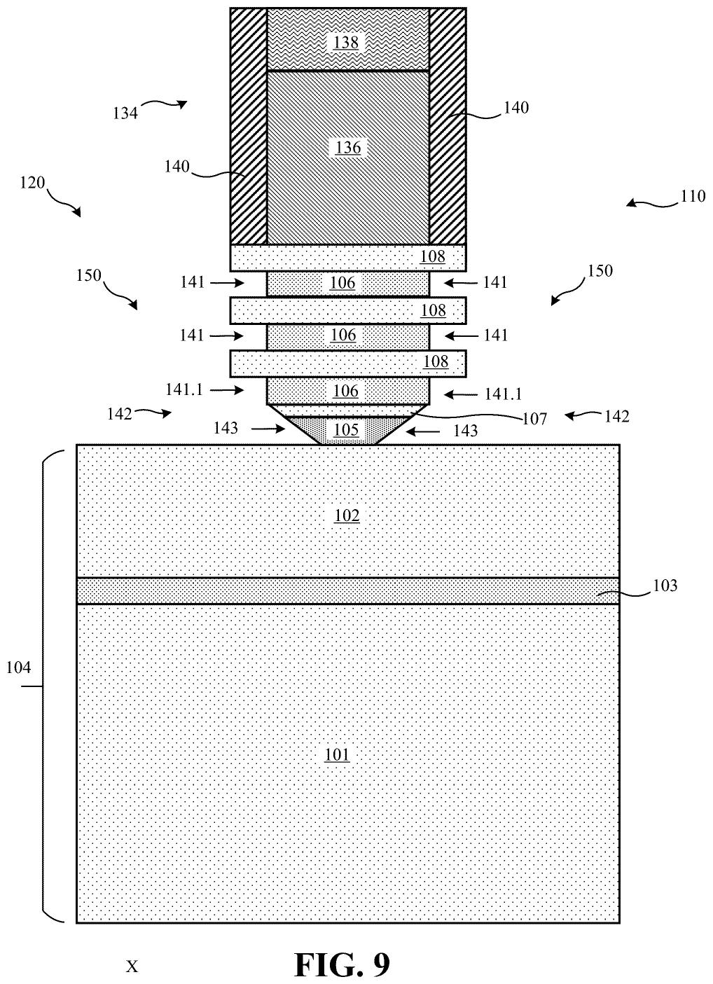

The retained one or more portions of one or more nanolayer stacks 120 may be such portions of the alternating nanolayers that were protected generally below and/or internal to respective sacrificial gate structures 134 and/or by the associated gate spacers 140 and the retained graded sacrificial nanolayer 105 portions thereunder and within the one or more S/D recesses 150. The retained graded sacrificial nanolayer 105 portions within the S/D recesses 150 may aide in or generally promote the etch profile of tapered indents 143 (illustratively depicted in FIG. 9). As such, as is depicted, respective sidewalls or end surfaces of the retained sacrificial nanolayers 106, the active nanolayers 108, the thin sacrificial nanolayer 107, may be coplanar with respective outer sidewalls of the associated gate spacers 140.

FIG. 9 depicts a cross-sectional view of the semiconductor IC device 100 after fabrication operations, in accordance with embodiments of the present disclosure. In the depicted fabrication stages, indents 141 are formed by removing respective portions of sacrificial nanolayers 106 that are not covered by the sacrificial gate 136 and tapered indents 143 are formed by removing respective portions of graded nanolayer 105 that are not covered by the sacrificial gate 136 as well as some portions that are covered by the sacrificial gate 136, as further described below.

Indents 141, 141.1 and tapered indents 143 may be formed by a reactive ion etch (RIE) process and a wet etch process, which can remove portions of the sacrificial nanolayers 106 not covered by the sacrificial gate 136 (and the sacrificial gate cap 138).

The etch at least partially or fully consumes the thin sacrificial nanolayer 107 due to the relative thinner vertical thickness thereof. The presence of thin sacrificial nanolayer 107 may generally promote the formation of indents 141.1 that are associated with the bottom most sacrificial nanolayer 106. In other words, the presence of thin sacrificial nanolayer 107 may result in the geometry of indents 141.1 substantially mirroring the geometry of one or more of the other indents 141 that are associated with the other sacrificial nanolayers 106. For example, the horizontal depth of indents 141 may be substantially the same as the horizontal depth of indents 143.

The etch consumes the portion of the graded nanolayer 105 that is upon substrate 104 outside of the footprint of sacrificial gate structure 134. Further, due to the microstructure gradient of the graded nanolayer 105, the etch horizontally removes portions of the graded nanolayer 105 at a different rate relative to other portions, which results in the tapered profile of tapered indent 143. For example, the etch consumes the bottommost portion nearest bottom surface 105.2 of the graded nanolayer 105 at a faster rate relative to the topmost portion nearest top surface 105.1 (shown in FIG. 4) of the graded nanolayer 105, which may result in a tapered linear, non-linear, stepped, curved, or the like, etched surface of graded nanolayer 105 inset relative to the outermost surfaces of the sacrificial gate 136. This tapered surface of graded nanolayer 105 generally forms the tapered geometry of the tapered indent 143.

In some implementations, such as long channel nanosheet transistors 110, the etch may be timed or otherwise controlled so that the opposing tapered indents 143 associated with distal ends of the graded nanolayer 105 do not merge. In other implementations, such as short channel nanosheet transistors 110, the etch may be timed or otherwise controlled so that the opposing tapered indents 143 that are associated with distal ends of the graded nanolayer 105 do merge. The merging of tapered indents 143 effectively creates an air, gas, ambient, or the like lateral gap or space between the substrate and the nanolayer stack 120. In this implementation, the nanolayer stack 120 may be structurally supported by the sacrificial gate structure 134 on the front/rear sides of the nanolayer stack 120 (e.g., the sidewalls of the nanolayer stacks 120 that are substantially coplanar with the STI regions 130 in the orthogonal cross-section view, as depicted in FIG. 5).

For clarity, the combined indent 141.1 and tapered indent 143 may, together, be referred to herein as tapered spacer indent 142.

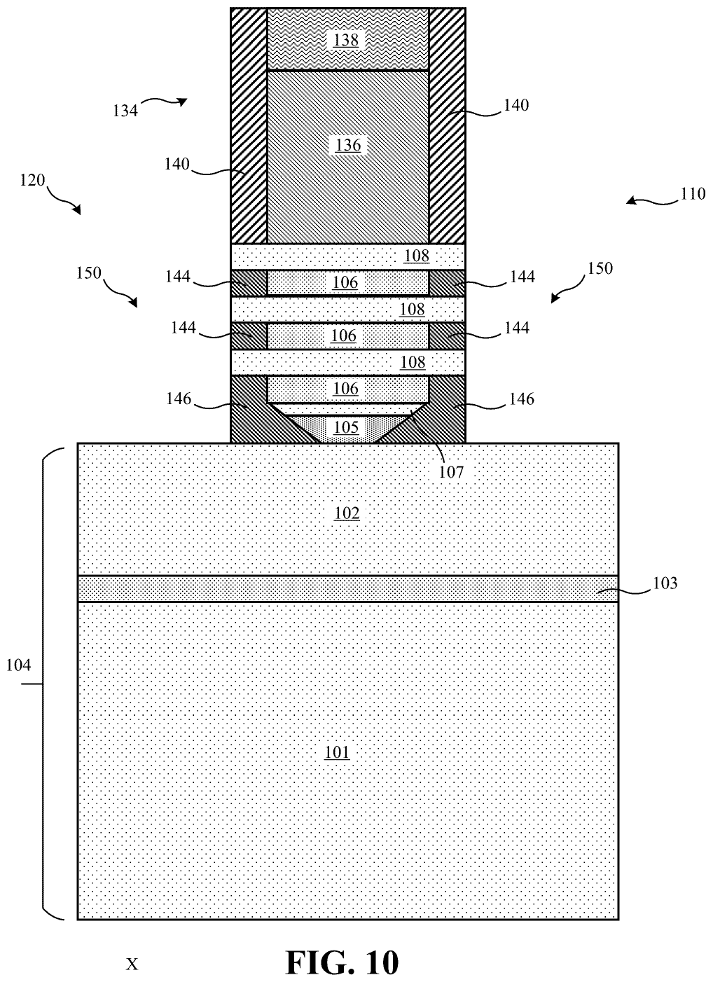

FIG. 10 depicts a cross-sectional view of the semiconductor IC device 100 after fabrication operations, in accordance with embodiments of the present disclosure. In the depicted fabrication stages, a respective inner spacer 144 is formed within the one or more indents 141 and a respective tapered inner spacer 146 is formed within the one or more tapered spacer indents 142. For clarity, in the examples where oppositely facing tapered indents 143 merge, the merged tapered inner spacer 146′ is formed accordingly.

The one or more inner spacers 144 and the one or more tapered spacer(s) 146, 146′ can be formed by ALD or CVD or any other suitable deposition technique that deposits material within the indents 141 or tapered spacer indents 142, thereby forming inner spacers 144 and tapered spacer(s) 146, 146′ respectively. In some examples, the inner spacers 144 and tapered spacer(s) 146, 146′ are composed of a low-K dielectric material (a material with a lower dielectric constant relative to SiO₂), SiN, SiO, SiBCN, SiOCN, SiCO, etc. or any other suitable dielectric material. In certain implementations, after the formation of the inner spacers 144 and tapered spacer(s) 146, 146′, an isotropic etch process is performed to create outer vertical surfaces of the inner spacers 144 and tapered spacer(s) 146, 146′ that align with outer vertical surfaces of the active nanolayers 108 and/or of the gate spacers 140.

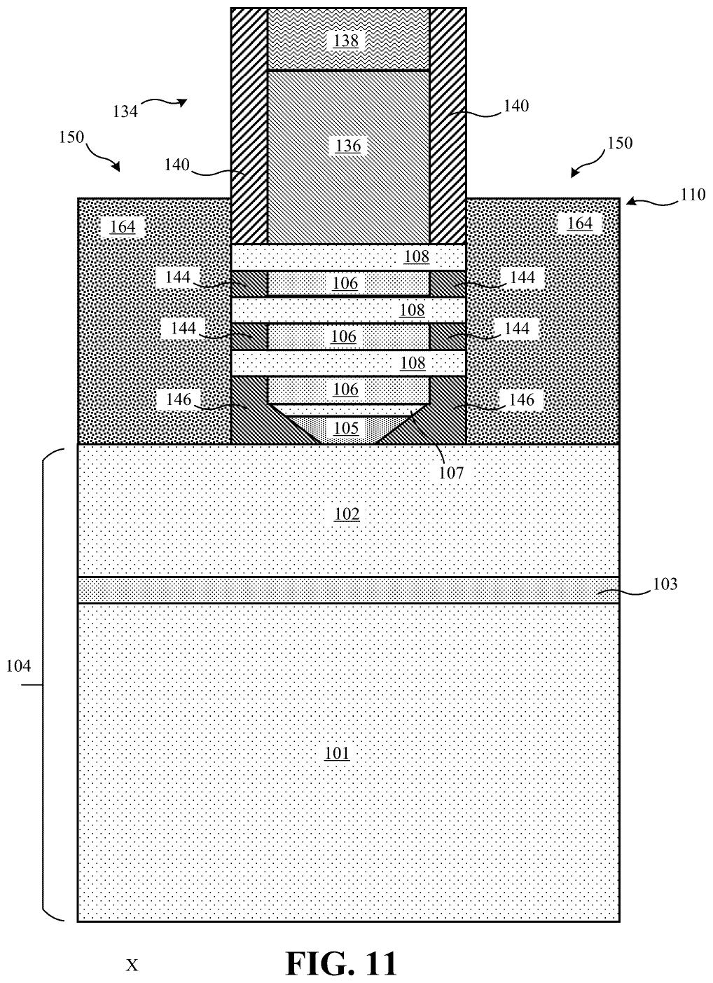

FIG. 11 depicts a cross-sectional view of the semiconductor IC device 100 after fabrication operations, in accordance with embodiments of the present disclosure. In the depicted fabrication stages, one or more source/drain (S/D) regions 164 are formed upon substrate 104 within S/D recesses 150.

Each S/D region 164 forms either a source or a drain, respectively, of respective one or more GAA FETs and is connected to respective end surfaces of active nanolayers 108 thereof. Each of the S/D region 164 is composed of a semiconductor material and a dopant. As used herein, a “source/drain” region can be a source region or a drain region depending on subsequent wiring and application of voltages during operation of the transistor. The semiconductor material that provides each of the S/D region 164 is composed of one of the semiconductor materials mentioned above for the semiconductor structure 102. The semiconductor material that provides the S/D region 164 can be compositionally the same, or compositionally different from each active nanolayers 108. The semiconductor material that provides each active nanolayers 108 is however compositionally different from each sacrificial nanolayer 106. The dopant that is present in the S/D region 164 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each of the S/D region 164 can have a dopant concentration of from 1×10²⁰ atoms/cm³ to 3×10²¹ atoms/cm³.

The S/D region(s) 164 may be formed by epitaxially growing a source/drain epitaxial region within the recess or opening between neighboring nanolayer transistors 110. In some examples, S/D region(s) 164 are formed by in-situ doped epitaxial growth. In some embodiments, the S/D region(s) 164 epitaxial growth may overgrow above the upper surface of the semiconductor IC device 100.

Suitable n-type dopants include but are not limited to phosphorous (P), and suitable p-type dopants include but are not limited to boron (B). The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In preferred embodiments, the S/D epitaxial growth conditions that promote in-situ Boron doped SiGe for p-type transistor and phosphorus or arsenic doped silicon or Si: C for n-type transistors.

In certain implementations, the S/D region(s) 164 may be overgrown and then partially recessed such that an upper portion of the S/D region(s) 164 are removed. For example, the upper portion of the one or more S/D region(s) 164 may be etched or otherwise removed. The etch may be timed or otherwise controlled to stop the removal of S/D region(s) 164 such that the top surface of S/D region(s) 164 is above the upper surface of the topmost active nanolayer 108 so as to appropriately contact the end surface of the topmost active nanolayer 108 channel and such that the top surface of the S/D region(s) 164 is below the upper surface of sacrificial gate structure 134 to maintain the ability to expose and remove the sacrificial gate structure 134.

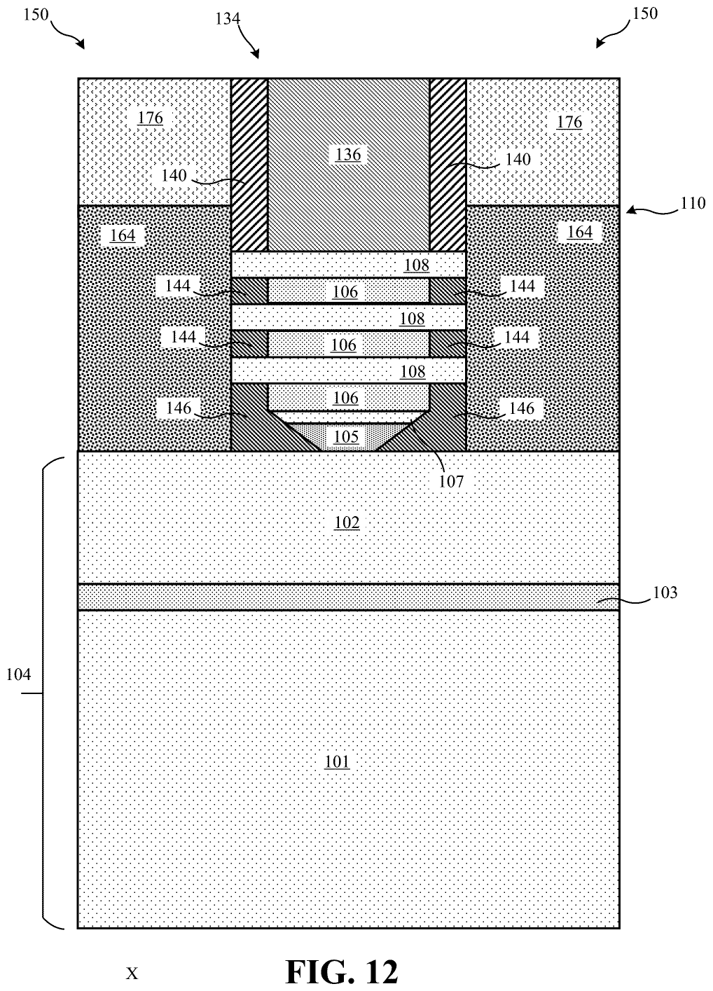

Further, as shown in FIG. 12, in the depicted fabrication stages, interlayer dielectric (ILD) 176 is formed upon the one or more source/drain (S/D) regions 164 and upon at least the sidewalls of the sacrificial gate structures 134 and may be further formed upon the STI region(s) 130 (not shown in the depicted cross-section).

The ILD 176 may be formed by depositing a dielectric material. The ILD 176 can be any suitable material, such as, for example, porous silicates, carbon doped oxides, silicon dioxides, silicon nitrides, silicon oxynitrides, or other dielectric materials. Any manner of forming the ILD 176 can be utilized. The ILD 176 can be formed using, for example, CVD, PECVD, ALD, flowable CVD, spin-on dielectrics, or PVD.

In an example, the ILD 176 may be formed to a thickness above the top surface of the sacrificial gate structures 134. Subsequently, a planarization process, such as a CMP, may be performed to remove the sacrificial gate cap 138 (shown in FIG. 11), to partially remove the excess ILD 176, and to partially remove the gate spacers 140. The planarization may also partially remove some of the sacrificial gate 136 or may at least expose the sacrificial gate 136 of the sacrificial gate structures 134. The CMP may create a planar or horizontal top surface for the semiconductor IC device 100. In other words, the respective top surfaces of ILD 176, gate spacers 140, sacrificial gates 136 may be coplanar.

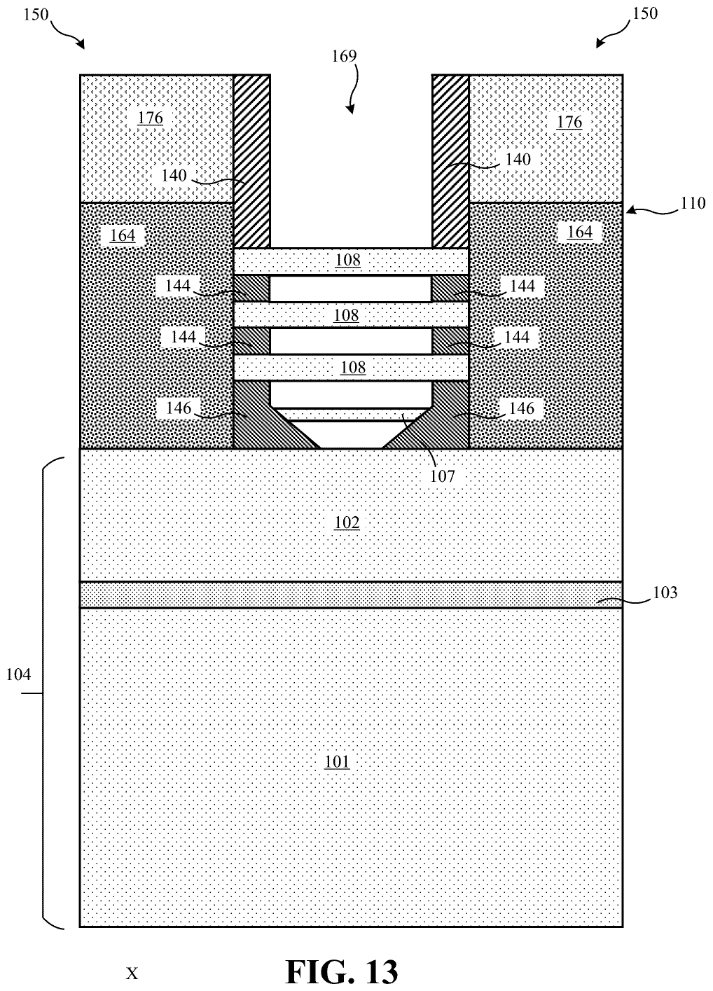

FIG. 13 depicts a cross-sectional view of the semiconductor IC device 100 after fabrication operations, in accordance with embodiments of the present disclosure. In the depicted fabrication stages, the sacrificial gate structures 134 are removed.

The sacrificial gate structure 134 may be removed by initially removing the sacrificial gate 136 and sacrificial gate oxide by a removal technique, such as one or more series of etches. For example, such removal may be accomplished by an etching process which may include a dry etching process such as RIE, plasma etching, ion etching or laser ablation. The etching can further include a wet chemical etching process in which one or more chemical etchants are used to remove the sacrificial gate 136 and sacrificial gate oxide of the sacrificial gate structures 134. Appropriate etchants may be used that remove the sacrificial gate 136 and/or sacrificial gate oxide selective to the active nanolayers 108, gate spacers 140, inner spacers 144, tapered inner spacers 146, or the like.

Further, in the depicted fabrication stages, the active nanolayers 108 are released by removing the sacrificial nanolayers 106.

The sacrificial nanolayers 106 may be removed by a removal technique, such as one or more series of etches. For example, the etching can include a wet chemical etching process in which one or more chemical etchants are used to remove the sacrificial nanolayers 106. Appropriate etchants may be used that remove the sacrificial nanolayers 106 selective to the active nanolayers 108, funneling inner spacers 122, gate spacers 140, or the like. After the removal of sacrificial nanolayers 106, there are void spaces between the active nanolayers 108.

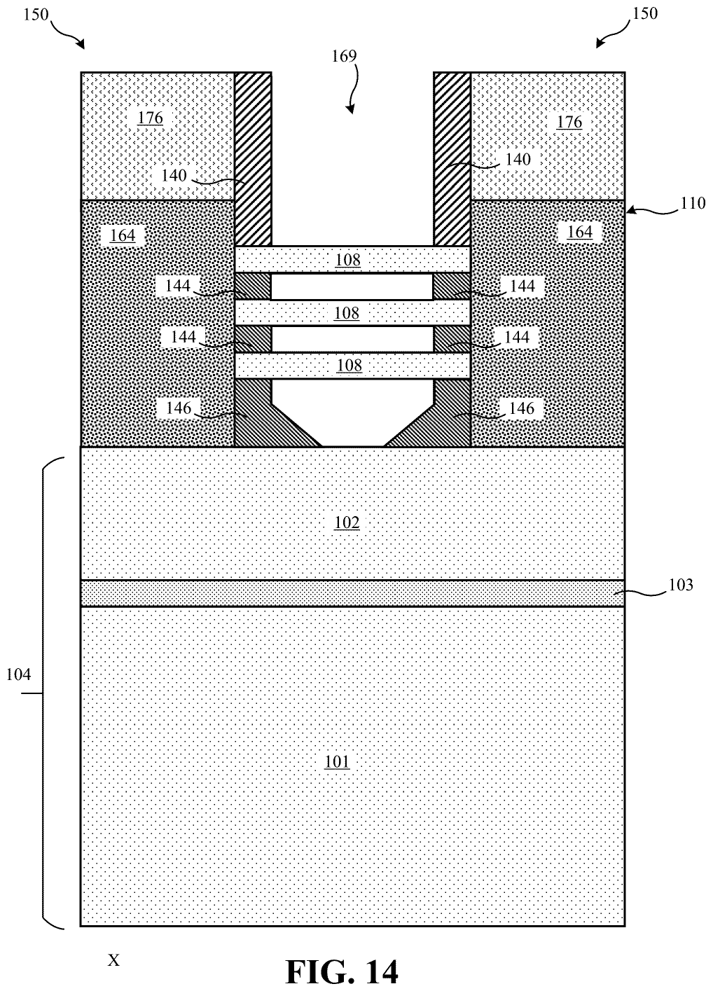

In some examples, the etch that removes the sacrificial gate 136 and/or the sacrificial nanolayers 106 also consumes the sacrificial thin nanolayer 107, because of the relatively small vertical thickness of the sacrificial thin nanolayer 107, even though the sacrificial thin nanolayer 107 and the active nanolayers 108 may be the same material. In other examples, residual sacrificial thin nanolayer 107 may exist after the etch that removes the sacrificial gate 136. In these cases, channel processing operations, such as channel cleaning, channel thinning, or the like, may remove or otherwise reduce the residual sacrificial thin nanolayer 107 material. In FIG. 14, the semiconductor IC device 100 is depicted after this residual sacrificial thin nanolayer 107 material is removed or reduced.

For clarity, the removal of at least the sacrificial gate 136 and the sacrificial nanolayers 106 generally form a replacement gate structure opening 169. As depicted, in one example, when tapered inner spacers 146 do not merge, the replacement gate structure opening 169 generally exposes at least a portion of the substrate 104. For example, the replacement gate structure opening 169 generally exposes at least a portion of the top surface of substrate 104. In alternative examples, when tapered inner spacers 146 do merge, the well or bottom surface of the replacement gate structure opening 169 is formed by the merged tapered inner spacer 146′.

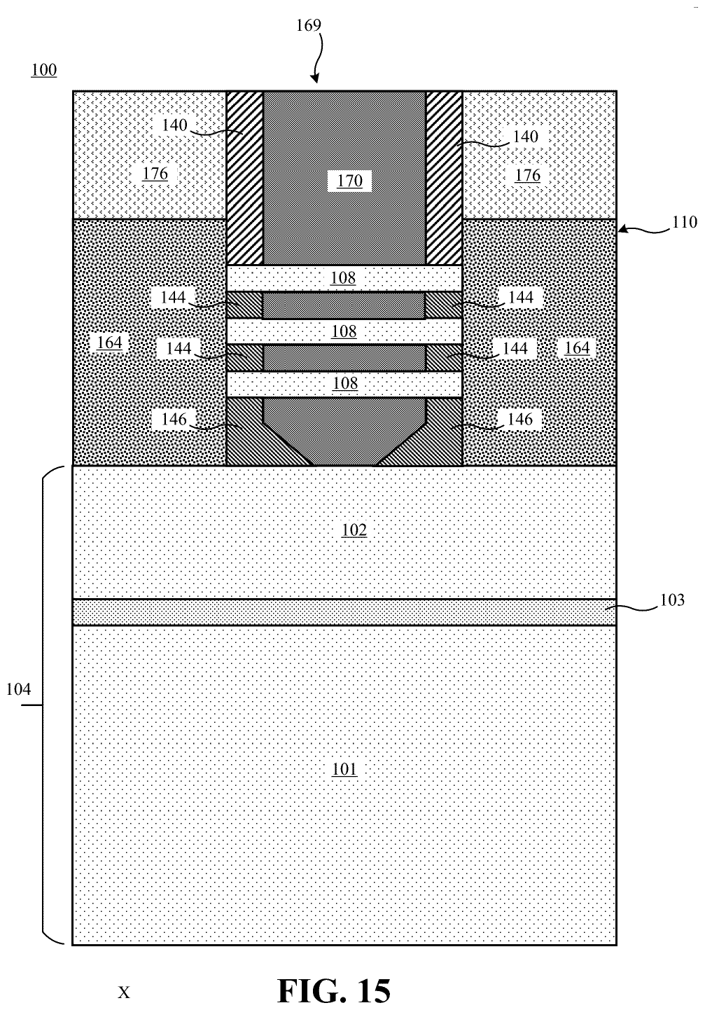

FIG. 15 depicts a cross-sectional view of the semiconductor IC device 100 after fabrication operations, in accordance with embodiments of the present disclosure. In the depicted fabrication stages, replacement gate structures 170 are formed around the active nanolayers 108 within replacement gate structure opening 169.

Replacement gate structure(s) 170 may be formed by initially forming an interfacial layer (not shown) on the interior surfaces of the gate structure opening 169 (e.g., interior surfaces of gate spacer 140, the interior surfaces of the active nanolayers 108, interior surfaces of inner spacers 144, the interior surfaces of tapered inner spacers 146, 146′, and when applicable, at least a portion of the substrate 104), etc. Then, a high-K layer is formed to cover the surfaces of exposed surfaces of the interfacial layer. The high-K layer can be deposited by any suitable techniques, such as ALD, CVD, metal-organic CVD (MOCVD), physical vapor deposition (PVD), thermal oxidation, combinations thereof, or other suitable techniques. A high-K dielectric material is a material with a higher dielectric constant than that of SiO₂, and can include e.g., LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr) TiO₃ (BST), Al₂O₃, Si₃N₄, oxynitrides (SiON), or other suitable materials. The high-κ layer can include a single layer or multiple layers, such as metal layer, liner layer, wetting layer, and adhesion layer.

Replacement gate structure(s) 170 may be further formed by depositing a work function metal (WFM) gate upon the high-k layer. The WFM gate can be comprised of metals, such as, e.g., copper (Cu), cobalt (Co), aluminum (Al), platinum (Pt), gold (Au), tungsten (W), titanium (Ti), nitride (N) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In various exemplary embodiments, the height of the WFM gate can be reduced by chemical-mechanical polishing (CMP) and/or etching. Therefore, the planarization process can be provided by CMP. Other planarization process can include grinding and polishing. In general, the work function metal (WFM) gate sets the threshold voltage (Vt) of the device. The high-K layer separates the WFM gate from the nanolayer channel (i.e., active nanolayers 108). Other metals that may be desired to further fine tune the effective work function (eWF) and/or to achieve a desired resistance value associated with current flow through the gate in the direction parallel to the plane of the nanolayer channel.

The one or more replacement gate structures 170 may be further formed by depositing a conductive fill gate upon the WFM gate. The conductive fill gate can be comprised of metals, such as but not limited to, e.g., tungsten, aluminum, ruthenium, rhodium, cobalt, copper, tantalum, titanium, carbon nanowire materials including graphene, or the like. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. After the replacement gate structure 170 formation, the top surface of the semiconductor IC device 100 may be planarized by a planarization technique such as a CMP, mechanical grinding process, or the like. After the planarization technique, respective top surfaces of the ILD 176, gate spacers 140, replacement gate structure(s) 170, may be horizontal and/or may be at least substantially coplanar.

In examples, semiconductor IC device 100 may be subjected to further fabrication stages, such as formation of an second ILD upon the ILD 176 and upon the replacement gate structure(s) 170, and/or formation of one or more middle of the line (MOL) contacts, such as a source MOL contact that melds with a source S/D region 164, a drain MOL contact that melds with a drain S/D region 164, or a gate MOL contact that melds with a replacement gate structure 170. Semiconductor IC device 100 may be subjected to further fabrication stages, such as formation of a back end of the line (BEOL) network upon the second ILD and upon the MOL contacts. The BEOL network may include metallization levels with signal wires and/or power rail wires, associated metallization dielectric layers, VIAs that connect the signal wires and/or power rail wires within the metallization levels with an underlying device or structure, and/or conductive bonding pads, or the like.

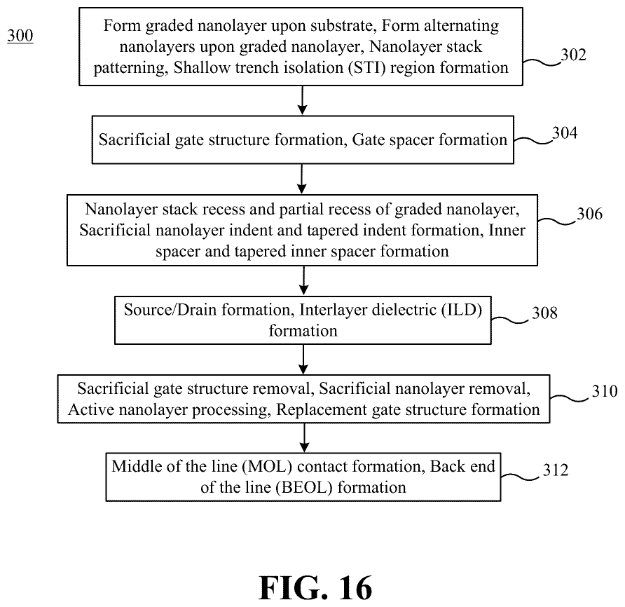

FIG. 16 depicts a flow diagram illustrating method 300 to fabricate a semiconductor IC device, such as semiconductor IC device 100. The depicted fabrication operations of method 300 are illustrated and described above with reference to one or more of FIG. 3 through FIG. 15 of the drawings, which describe the fabrication of semiconductor IC device 100, though the fabrication operations described in method 300 may be used to fabricate other types of semiconductor IC devices. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming a graded nanolayer upon a substrate, with forming alternating nanolayers over the graded nanolayer, patterning the nanolayers into one or more nanolayer stacks, and forming shallow trench isolation regions upon the substrate adjacent to the nanolayer stack or between the nanolayer stacks. For example, method 300 may include forming graded nanolayer 105 upon the substrate 104, with forming an alternating series of sacrificial nanolayers 106 and active nanolayers 108 over the graded nanolayer 105. Further, method 300 may include pattering the nanolayers to form one or more nanolayer stack(s) 120 and forming STI regions 130 adjacent thereto or therebetween. For example, predetermined portions of the nanolayers may be removed and a well within the substrate 104 may be formed. The portions of the nanolayers that remain may effectively form the one or more nanolayer stacks 120 and respective STI regions 130 may be formed within the substrate well between the nanolayer stacks 120.

At block 304, method 300 may further continue with forming one or more sacrificial gate structure(s) and with forming one or more gate spacers upon the one or more sacrificial gate structure(s). For example, method 300 may include forming one or more sacrificial gate structures 134 upon the substrate 104, upon the STI regions 130, and upon and around the nanolayer stack(s) 120. Further, method 300 may include forming one or more gate spacer(s) 140 upon the substrate 104 and/or upon the STI regions 130 and upon the sidewall(s) of the sacrificial gate structures 134. For example, the gate spacer(s) 140 may be formed upon the STI regions 130, may be formed upon and around nanolayer stack(s) 120, and may be formed upon and around the one or more sacrificial gate structure(s) 134, respectively.

At block 306, method 300 may further continue with recessing the nanolayer stacks and partially recessing the graded nanolayer, with indenting the sacrificial nanolayers within the nanolayer stacks, with forming a tapered indent within the graded nanolayer, with forming a respective inner spacer within the indent, and with forming a respective tapered inner spacer within the tapered indent.

For example, method 300 may include forming S/D recesses 150 within the nanolayer stack(s) 120 between gate spacers 140 associated with neighboring sacrificial gate structures 134. Further, method 300 may include etching and indenting the sacrificial nanolayers 106 within nanolayer stack(s) 120, thereby forming an indent 141 and etching and indenting the graded nanolayer 105 within nanolayer stack(s) 120, thereby forming tapered indent 143. An adjacent or otherwise combined indent 141.1 and tapered indent 143 may be combined to form tapered inner spacer indent 142. In some examples, two opposite facing tapered indents 143 may merge.

Method 300 may further include forming an inner spacer 144 within a respective indent 141 and with forming tapered inner spacer 146 within a respective tapered inner spacer indent 142 or with forming a merged tapered inner spacer 146′ within the opening associated with the merged tapered inner spacer indents 142.

At block 308, method 300 may further continue with forming one or more S/D regions and with forming an ILD. For example, method 300 may include forming respective S/D regions 164 upon the substrate 104 in contact with respective end surfaces of the active nanolayers 108. Still further, method 300 may include forming ILD 176 upon S/D region(s) 164, upon STI regions 130, and upon the sidewall(s) of the gate spacers 140 associated with the sacrificial gate structures 134.

At block 310, method 300 may continue with removing the one or more sacrificial gate structure(s), with removing the sacrificial nanolayers, and with forming a replacement gate structure within the void or recess formed by the absence of the respective sacrificial gate structure and sacrificial nanolayers. For example, method 300 may include removing the sacrificial gate structure(s) 134, with removing the sacrificial nanolayers 106, with removing the sacrificial thin nanolayer 107, with removing remaining graded nanolayer 105, and with forming a respective replacement gate structure 170 within a replacement gate opening 169. The sacrificial thin nanolayer 107 may be removed by the etch that removes the sacrificial gate 136 and the sacrificial nanolayers 106 or may be subsequently removed by active nanolayer 108 channel processing stages such as channel cleaning or thinning processes.

At block 312, method 300 may continue with MOL contact formation and with frontside back end of line (BEOL) network formation. For example, method 300 may include forming a second ILD upon the replacement gate structure(s) 170 and upon the ILD 176 and with forming a frontside contact upon one or more S/D regions 164 or one or more replacement gate structures 170. Further, method 300 may include forming the frontside BEOL network upon the second ILD and upon the frontside contacts. In some implementations, method 300 may also include subsequent fabrication stages to, for example, fabricate an IC chip, an end product, or the like.

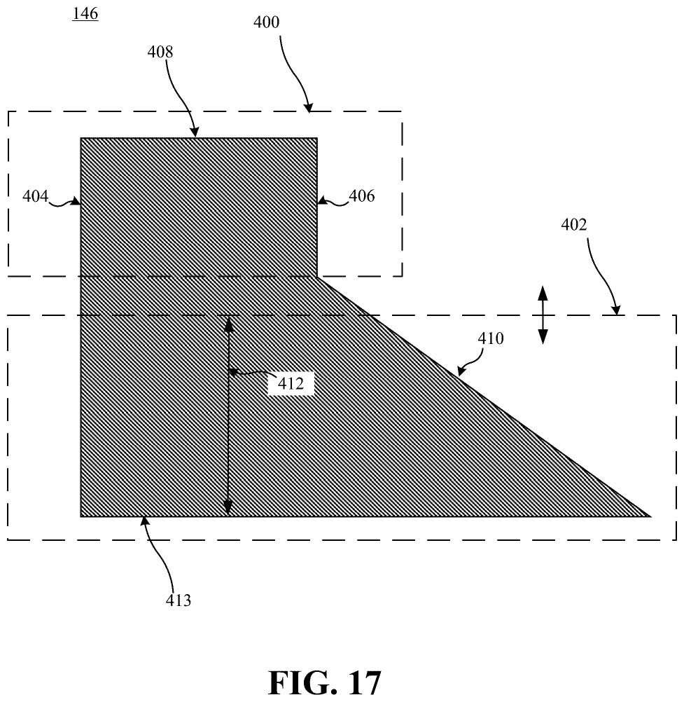

FIG. 17 depicts a cross section view of a tapered inner spacer 146, according to one or more embodiments of the disclosure. The tapered inner spacer(s) 146 include a base region 402 that extends into the replacement gate structure 170. A vertical thickness or height 412 of the base region 402 may decrease in proportion to a horizontal dimension into the replacement gate structure 170 to which it extends. The tapered inner spacer(s) 146 may include a mirrored inner spacer region 400 which substantially shares the same geometry of other inner spacers 144 within the nanosheet transistor 110. In an illustrative geometry, the base region 402 of the tapered inner spacer(s) 146 is below the mirrored inner spacer region 400 of the tapered inner spacer(s) 146. In some embodiments, there may be a gap between the mirrored inner spacer region 400 and the base region 402, due to the presence of residual sacrificial thin nanolayer 107 at the time of tapered inner spacer 146 formation.

The tapered inner spacer(s) 146 include a bottom surface 413 within the base region 402. The bottom surface may be coincident with the top surface of the substrate 104. The base region 402 also includes a tapered surface 410 that extends or protrudes inwardly past a first sidewall of the replacement gate structure 170 (e.g., left-facing sidewall) toward a second sidewall of the replacement gate structure 170 (e.g., right-facing sidewall). Tapered surface has a negative or downward (as depicted) sloping surface or wall. The vertical thickness or height 412 of the base region 402 generally decreases along the length of tapered surface 410 due to the negative or downward (as depicted) sloping surface of tapered surface 410. Generally, the base region 402 extends or protrudes inwardly beyond an associated plane that is coplanar with one or more sidewalls of the replacement gate structure 170, and resultantly reduces a gate length (shown, for example, as gate length 171 in FIG. 1 and in FIG. 2) at a bottom surface or portion of the replacement gate structure 170 that is located between the substrate 104 and a bottommost active nanolayer 108.

Semiconductor IC device 100, or the like, may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A transistor comprising:
a substrate;
a gate around a plurality of channels and directly upon the substrate; and
a tapered inner spacer directly upon the substrate and below a bottommost channel of the plurality of channels, the tapered inner spacer comprising a base region that extends inwardly beyond a plane that is coplanar with a sidewall of the gate.

2. The transistor of claim 1, wherein the base region reduces a gate length of the gate adjacent to the base region.

3. The transistor of claim 1, further comprising:
a source/drain (S/D) region directly upon the tapered inner spacer and directly upon respective end surface of the plurality of channels.

4. The transistor of claim 1, further comprising a gate spacer that is located above a topmost channel of the plurality of channels.

5. The transistor of claim 4, wherein the gate comprises a first gate length adjacent to the gate spacer and a second gate length adjacent to the base region and wherein the second gate length is less than the first gate length.

6. The transistor of claim 4, wherein the tapered inner spacer comprises a mirrored inner spacer region and wherein respective sidewalls of the mirrored inner spacer region are coplanar with respective sidewalls of the gate spacer.

7. The transistor of claim 1, wherein the base region comprises a bottom surface and a tapered surface with a vertical thickness therebetween that decreases in proportion to a degree to which the base region extends inwardly beyond the plane that is coplanar with the sidewall of the gate.

8. A transistor comprising:
a gate around a plurality of channels;
a first tapered inner spacer below a bottommost channel of the plurality of channels, the first tapered inner spacer comprising a first base region that extends inwardly beyond a first plane that is coplanar with a first sidewall of the gate; and
a second tapered inner spacer below a bottommost channel of the plurality of channels, the second tapered inner spacer comprising a second base region that extends inwardly beyond a second plane that is coplanar with a second sidewall of the gate that is opposing the first sidewall of the gate.

9. The transistor of claim 8, wherein the first base region and the second base region reduce a gate length of the gate between the first base region and the second base region.

10. The transistor of claim 8, further comprising:
a first source/drain (S/D) region directly upon the first tapered inner spacer and directly upon respective first end surfaces of the plurality of channels; and
a second S/D region directly upon the second tapered inner spacer and directly upon respective second end surfaces of the plurality of channels.

11. The transistor of claim 8, further comprising a gate spacer that is located above a topmost channel of the plurality of channels.

12. The transistor of claim 11, wherein the gate comprises a first gate length between the gate spacer and a second gate length between the first base region and the second base region and wherein the second gate length is less than the first gate length.

13. The transistor of claim 11, wherein the first tapered inner spacer comprises a first mirrored inner spacer region, wherein the second tapered inner spacer comprises a second mirrored inner spacer region, wherein respective sidewalls of the first mirrored inner spacer region are coplanar with respective sidewalls of the gate spacer, and wherein respective sidewalls of the second mirrored inner spacer region are coplanar with respective sidewalls of the gate spacer.

14. The transistor of claim 8, wherein the first base region comprises a first bottom surface and a first tapered surface with a vertical thickness therebetween that decreases in proportion to a degree to which the first base region extends inwardly beyond the first plane.

15. The transistor of claim 8, wherein the first base region and the second base region are merged.

16. The transistor of claim 15, wherein the merged first base region and second base region is between the gate and a substrate.

17. A method of forming a semiconductor integrated circuit (IC) device comprising:
forming a graded nanolayer directly upon a substrate;
indenting the graded nanolayer to form a tapered inner spacer opening; and
forming a tapered inner spacer within the tapered inner spacer opening.

18. The method of claim 17, further comprising:
forming a sacrificial nanolayer directly upon the graded nanolayer.

19. The method of claim 17, further comprising:
forming a gate directly upon the tapered inner spacer.

20. The method of claim 19, wherein the tapered inner spacer comprises a base region and wherein the base region reduces a gate length of the gate adjacent to the base region.

21. A transistor comprising:
a gate around a channel that extends beyond both a first sidewall of the gate and a second sidewall of the gate; and
a tapered inner spacer directly upon the gate and directly upon a bottom surface of the channel, the tapered inner spacer comprising a base region that protrudes beyond the first sidewall of the gate toward the second sidewall of the gate.

22. The transistor of claim 21, wherein the base region reduces a gate length of the gate adjacent to the base region.

23. The transistor of claim 21, wherein the gate has a first gate length above the channel and a second gate length adjacent to the base region, and wherein the second gate length is less than the first gate length.

24. The transistor of claim 23, wherein the tapered inner spacer further comprises a mirrored inner spacer region and wherein the gate has the first gate length adjacent to the mirrored inner spacer region.

25. The transistor of claim 21, wherein the base region comprises a bottom surface and a tapered surface with a vertical thickness therebetween that decreases in proportion to a degree to which the base region protrudes beyond the first sidewall of the gate toward the second sidewall of the gate.
